(19) United States
(12) Patent Application Publication
(10) Pub. No.: US 2024/0334663 A1
(43) Pub. Date: Oct. 3, 2024

(54) DISPLAY DEVICE

(71) Applicant: LG DISPLAY CO., LTD., Seoul (KR)

(72) Inventors: Dae Yun KIM, Paju-si (KR); Jeong Jo LEE, Paju-si (KR); Eun Jeong YANG, Paju-si (KR)

(73) Assignee: LG DISPLAY CO., LTD., Seoul (KR)

(21) Appl. No.: 18/590,857

(22) Filed: Feb. 28, 2024

(30) Foreign Application Priority Data
Mar. 30, 2023 (KR) 10-2023-0041887

(51) Int. Cl. H05K 7/20

(52) U.S. Cl. CPC H05K 7/20954; H05K 7/20127

(57) ABSTRACT

The present disclosure relates to a display device including a printed circuit board disposed on a rear surface of a display panel, and a cover bottom disposed on the rear surface of the display panel. The cover bottom includes at least one heat dissipation tunnel into which updraft generated by the heat from the printed circuit board is introduced. The heat dissipation tunnel includes at least one inlet spaced apart from the printed circuit board on one side of the rear surface of the display panel, and at least one outlet disposed on the other side of the display panel, through which the updraft rising across the rear surface of the display panel is discharged.

### CROSS-REFERENCE TO RELATED APPLICATION

This application claims priority to and the benefit of Korean Patent Application No. 10-2023-0041887, filed Mar. 30, 2023, the disclosure of which is incorporated herein by reference in its entirety.

### BACKGROUND

### Technical Field

The present disclosure relates to a display device.

### Discussion of the Related Art

Organic light emitting display devices reproduce images by emitting light using an organic light emitting diode (OLED) placed in each pixel according to an input image signal. The organic light emitting display devices have a fast response speed and high luminous efficiency, luminance, and viewing angle, and have an excellent contrast ratio and color reproducibility as it can express black grayscales in full black. No backlight unit is required for these organic light emitting display devices.

In recent years, the display devices that use a light emitting diode (LED), an inorganic light-emitting device, as the light-emitting element of pixels have been attracted attention as the next generation of the display devices. Because the LEDs are made of inorganic materials, they don't require a separate encapsulation layer to protect the organic material from moisture, and they have an excellent reliability and a longer life than the OLEDs. The LEDs also have a fast light-up speed, excellent luminous efficiency, and are resistant to impact.

When the temperature distribution of a display panel is uneven during operation of a display device, the image quality of the image reproduced on the display panel is degraded due to electronic elements with temperature characteristics. For example, if the difference between the maximum temperature and the minimum temperature of the display panel becomes large, it may cause a color difference in which characteristic colors appear strongly in the image displayed on the display panel.

### SUMMARY

Accordingly, embodiments of the present disclosure are directed to a display device that substantially obviates one or more of the problems due to limitations and disadvantages of the related art.

An aspect of the present disclosure is to provide a display device capable of reducing a temperature difference in the temperature distribution of a display panel.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a printed circuit board (PCB) disposed on a rear surface of a display panel; and a cover bottom (in other words, bottom cover) disposed on the rear surface of the display panel. The cover bottom includes at least one heat dissipation tunnel into which updraft generated by the heat from the printed circuit board is introduced.

According to the present disclosure, the temperature of the PCB may be reduced by inducing natural convection of the hot updraft caused by the buoyancy generated by the heating of the PCB into a flow path formed on the rear surface of the display panel, as well as reducing the temperature difference with the maximum temperature of the display panel.

According to the present disclosure, the display quality may be improved by minimizing visible spots or color differences due to the temperature difference in the display panel.

According to the present disclosure, when the display panel is used as a vibration plate of a speaker, the cover bottom covering a vibration generator of the speaker is made to have an open structure, thereby not requiring a vent hole for the speaker.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a block diagram illustrating a configuration of a display device according to one embodiment of the present disclosure;

FIG. 2 is a partial cross-sectional view illustrating pads disposed on the outermost portion of a display panel and a side wiring according to one embodiment of the present disclosure;

FIG. 3 is a perspective view illustrating a tiled display device according to one embodiment of the present disclosure;

FIG. 4 is a block diagram schematically illustrating control boards connected to a plurality of printed circuit boards and a system board connected to the control boards;

FIG. 5 is a plan view illustrating a planar structure of a display panel according to one embodiment of the present disclosure;

FIG. 6 is a cross-sectional view illustrating in detail a cross-sectional structure of a display panel according to one embodiment of the present disclosure;

FIG. 7 is a plan view illustrating a rear surface of a display module according to one embodiment of the present disclosure;

FIG. 8 is an exploded perspective view illustrating a display module according to one embodiment of the present disclosure;

FIG. 9 is a cross-sectional view illustrating an inlet of a cover bottom cut along line “I-I′” in FIG. 7;

FIG. 10 is a cross-sectional view illustrating an outlet of the cover bottom cut along line “II-II” in FIG. 7;

FIG. 11 is a cross-sectional view illustrating the geometric relationship between components on a rear surface of a display module;

FIG. 12 is a plan view illustrating a rear surface of a display module according to another embodiment of the present disclosure;

FIGS. 13 to 17 are drawings illustrating simulations to verify the effectiveness of compensating for temperature differences in a display panel due to heat dissipation tunnels disposed on a rear surface of a display module; and

FIG. 18 is a plan view illustrating a rear surface of a display module according to further another embodiment of the present disclosure.

### DETAILED DESCRIPTION

The advantages and features of the present disclosure and methods for accomplishing the same will be more clearly understood from embodiments described below with reference to the accompanying drawings. However, the present disclosure is not limited to the following embodiments, but may be implemented in various different forms; rather, the present embodiments will make the disclosure of the present disclosure complete and allow those skilled in the art to fully comprehend the scope of the present disclosure.

In describing the present disclosure, detailed descriptions of known related technologies may be omitted so as not to unnecessarily obscure the subject matter of the present disclosure.

The terms such as “comprising”, “including”, “having” and “consisting of” used herein are generally intended to allow other components to be added unless the terms are used with the term “only”. References to the singular shall be construed to include the plural unless expressly stated otherwise.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms used in the embodiments of the disclosure (including technical and scientific terms) are to be construed as they would be commonly understood by one of ordinary skill in the art to which the invention belongs, unless otherwise specifically defined and described, and commonly used terms, such as dictionary defined terms, are to be construed in light of their contextual meaning in the relevant art.

Hereinafter, preferred embodiments of the present disclosure will be described in detail with reference to the accompanying drawings.

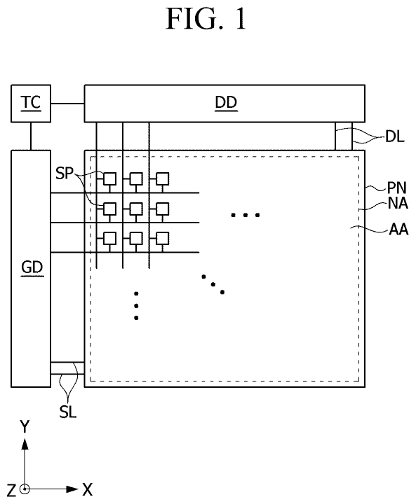

Referring to FIG. 1, a display device includes a display panel PN having a plurality of pixels disposed in a display area AA, and a driving circuit to drive the pixels.

The display panel PN may be a panel having a rectangular structure with a length in the X-axis direction, a width in the Y-axis direction, and a thickness in the Z-axis direction. Each of the pixels may include a plurality of subpixels SP with different colors. The driving circuit includes a data driver DD, a gate driver GD, and a timing controller TC that controls the gate driver GD and the data driver DD. The display area AA on which an input image is displayed on the display panel PN may be a screen visible from a front surface of the display panel PN.

The input image is displayed on the subpixels SP disposed in the display area AA of the display panel PN. Each of the subpixels SP includes a light emitting element and a pixel circuit that drives the light emitting element. The light emitting element may be a light emitting diode (LED) or a micro light emitting diode (micro LED).

On the display panel PN, a plurality of scan wirings (in other words, scan lines) SL and a plurality of data wirings (in other words, data lines) DL are arranged to cross each other. Each of the subpixels SP is connected to a scan wiring SL and a data wiring DL. Power supply wirings (in other words, power supply lines) omitted in FIG. 1 may be connected to each of the subpixels SP. In a display panel PN, a non-display area NA may be disposed outside the display area AA.

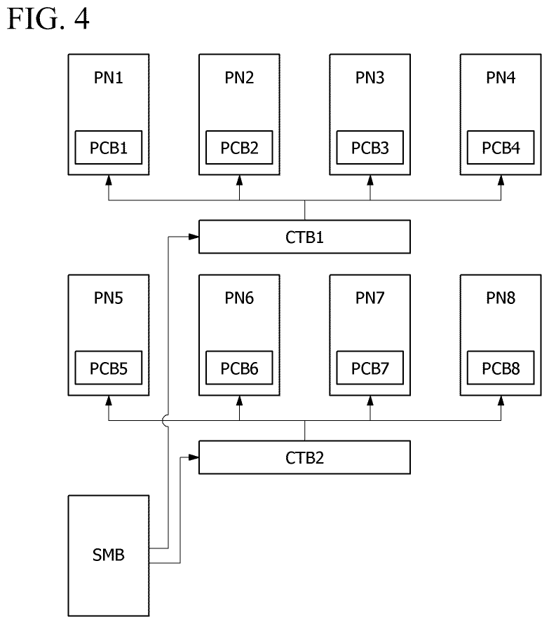

The gate driver GD supplies scan signals to the scan wirings SL in response to a gate control signal provided by the timing controller TC. The gate driver GD may be disposed at least in the non-display area NA of the display panel PN, as shown in FIG. 1, or disposed in the display area AA, as shown in FIG. 4.

The data driver DD converts the image data received from the timing controller TC into a reference compensation voltage and outputs a data voltage in response to a data control signal provided by the timing controller TC. The data voltage output from the data driver DD is supplied to the data wirings DL.

The timing controller TC aligns image data input from the outside and supplies the aligned image data to the data driver DD. The timing controller TC may generate gate control signals and data control signals based on timing signals synchronized with input image signals, for example, dot clock signals, data enable signals, and horizontal/vertical synchronization signals. The timing controller TC supplies the gate control signals to the gate driver GD and the data control signals to the data driver DD to control the timing of the operation of the gate driver GD and the data driver DD.

The non-display area NA may have link wirings (in other words, link lines) and pad electrodes disposed therein to transmit signals to the subpixels SP in the display area AA. Furthermore, one or more of a gate driver IC in which circuits for the gate driver GD are integrated and a data driver IC in which circuits for the data driver DD are integrated may be disposed in the non-display area NA. The non-display area NA may be located on the rear surface of the display panel PN, i.e., on the rear surface where there are no subpixels SP, or it may be minimized to the extent that it is invisible when an image is displayed on the display panel PN.

The drivers such as the gate driver GD, the data driver DD, and the timing controller TC may be connected to the display panel PN in a variety of ways. For example, the gate driver GD may be disposed in a gate in panel (GIP) fashion in the non-display area NA, or in a gate in active area (GIA) fashion between subpixels SP in the display area AA. For example, the data driver DD and the timing controller TC may be formed on separate flexible films and printed circuit boards (hereinafter referred to as “PCB”), and the data driver DD and the timing controller TC may be electrically connected to the display panel PN by bonding the flexible films and the PCBs to pad electrodes formed on the non-display area NA of the display panel PN.

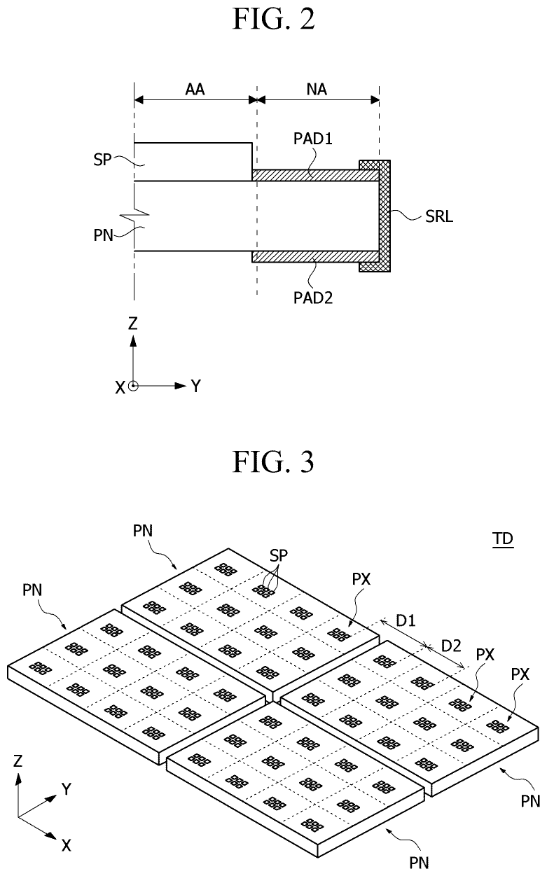

A side wiring (in other words, side line) for connecting the signal wirings (in other words, signal lines) on the front surface of the display panel PN to the pad electrodes on the rear surface of the display panel PN may be formed on the outermost side surface of the display panel PN. Such a method of providing an electrical connection between the front surface and the rear surface of the display panel PN via the side wiring may maximally minimize the non-display area NA visible on the front surface of the display panel PN. In FIG. 2, “SRL” denotes this side wiring. When the gate driver GD, the data driver DD, and the timing controller TC are connected to the display panel PN in the above manner, a screen without a bezel may be substantially realized.

Referring to FIG. 2, a plurality of pad electrodes are disposed in the non-display area NA of the display panel PN to transmit various signals to the subpixels SP. For example, a first pad electrode PAD1, which transmits signals to the subpixels SP, may be disposed in the non-display area NA located at the front surface of the display panel PN. A second pad electrode PAD2, which is electrically connected to circuit components such as the flexible films and the PCBs, is disposed in the non-display area NA at the rear surface of the display panel PN. Only the pad area in which the first pad electrode PAD1 is located is disposed in the non-display area NA located at the front outermost portion of the display panel PN on which an image is displayed, thereby minimizing the size of the non-display area.

Various signal wirings associated with the subpixels SP, such as the scan wiring SL or the data wiring DL, may extend into the non-display area NA and be electrically connected to the first pad electrode PAD1.

The display panel PN may include the side wiring SRL disposed on the outermost side surface of the display panel PN. The side wiring SRL may electrically connect the first pad electrode PAD1 disposed on the front outermost portion of the display panel PN and the second pad electrode PAD2 disposed on the rear outermost portion of the display panel PN while traversing the side surface of the display panel PN. The signals output from the circuit components disposed at the rear surface of the display panel PN may be transmitted to the subpixels SP within the display area AA via the second pad electrode PAD2, the side wiring SRL, and the first pad electrode PAD1. Accordingly, the area of the non-display area NA on the front surface of the display panel PN may be minimized by forming a signal transmission path traversing the front, side, and rear surfaces at the outermost portion of the display panel PN.

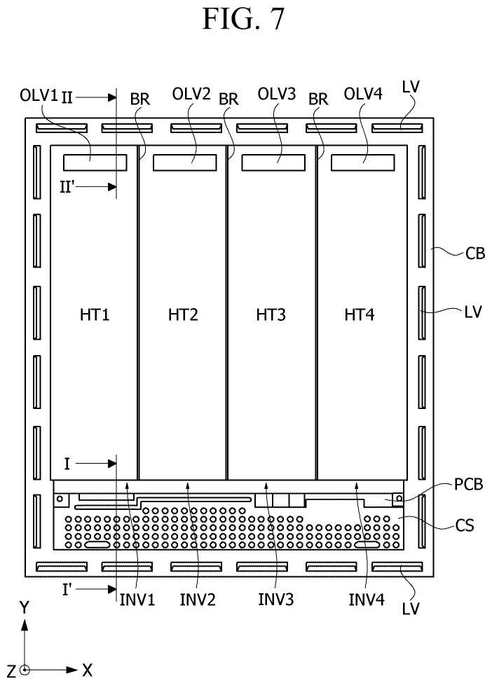

As illustrated in FIG. 3, a plurality of display modules may be combined on a plane to be implemented as a large-screen tiled display device. Each of the display modules includes a single sheet of a display panel PN, a driving circuit for the display panel PN, and circuit components and module cover members coupled to the rear surface of the display panel PN as illustrated in FIGS. 7 to 13.

Referring to FIG. 3, a large-screen tiled display device TD includes a plurality of display modules disposed in an X-Y plane. Each of the display modules includes a display panel PN on which an input image is reproduced. When the non-display area NA at the front outermost portion of each display panel PN is minimized, the large-screen image with no visible seams between neighboring display panels PN may be reproduced.

The display panels PN may be assembled in a plane such that the spacing D1 between the outermost pixel PX of one display panel PN and the outermost pixel PX of another display panel PN adjacent to that display panel PN is substantially the same as the spacing D2 between neighboring pixels PX within the display area of the display panel PN. As a result, the spacing D1 and D2 between the neighboring pixels PX becomes the same throughout the large-screen display area of the tiled display device TD, and thus the seam area is not visible.

In the tiled display device TD, multiple display modules may share one timing controller TC. A host system may be connected to a plurality of timing controllers TC, may transmit image signals to the timing controllers TC to be reproduced on all of the display panels PN implementing the large-screen of the tiled display device TD, and may synchronize the timing controllers TC.

Referring to FIG. 4, each of the display modules may include a single sheet of a display panel PN and one PCB. A system board SMB is connected to M (M is an integer greater than or equal to 2) control boards (for example, it includes a first control board CTB1 and a second control board CTB2, but not limited thereto). Each of the control boards (for example, it includes a first control board CTB1 and a second control board CTB2, but not limited thereto) is connected to N (N is an integer greater than M) PCBs.

A first control board CTB1 may be connected to the PCBs of a first to fourth display modules PCB1 through PCB4 via flexible films or cables. A second control board CTB2 may be connected to the PCBs of a fifth to eighth display modules PCB5 through PCB8 via flexible films or cables. The system board SMB may be connected to the first and second control boards CTB1, CTB2 via flexible films or cables.

The system board SMB may be a main board of the host system. The system board SMB includes a user interface port to receive user input, an external interface port connected to external devices, a communication module to realize or delay various communication protocols, a processor to process multi-media signals, a central processing unit (CPU), and a main power supply. The system board SMB sends an input image signal and a timing signal to the first and second control boards CTB1, CTB2. The timing controllers TC mounted on the first and second control boards CTB1, CTB2 transmits the received image signal to the data driver DD and controls the data driver DD and the gate driver GD based on the timing signal. The driving circuits (for example, the data driver DD and the gate driver GD) for the N display modules write image data to the corresponding display panels PN under the control of one timing controller TC.

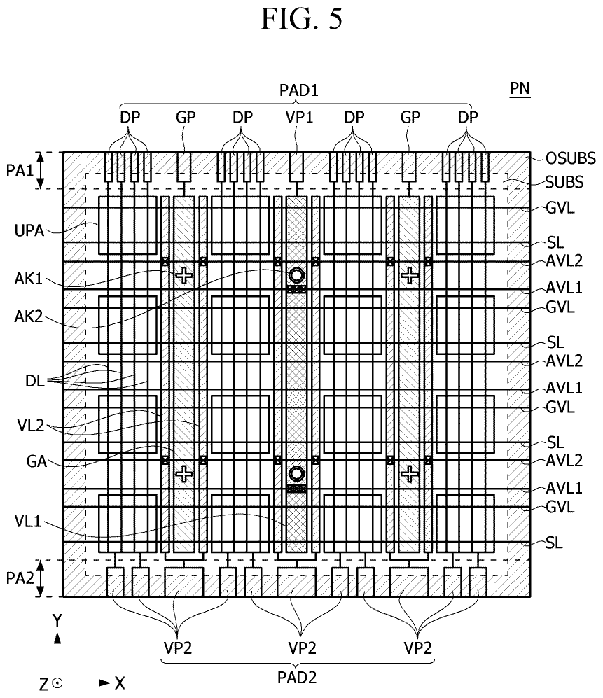

FIG. 5 is a plan view illustrating a planar structure of a display panel according to one embodiment of the present disclosure.

Referring to FIG. 5, a display panel PN includes a substrate SUBS on which a pixel array and a circuit for a gate driver GD are disposed.

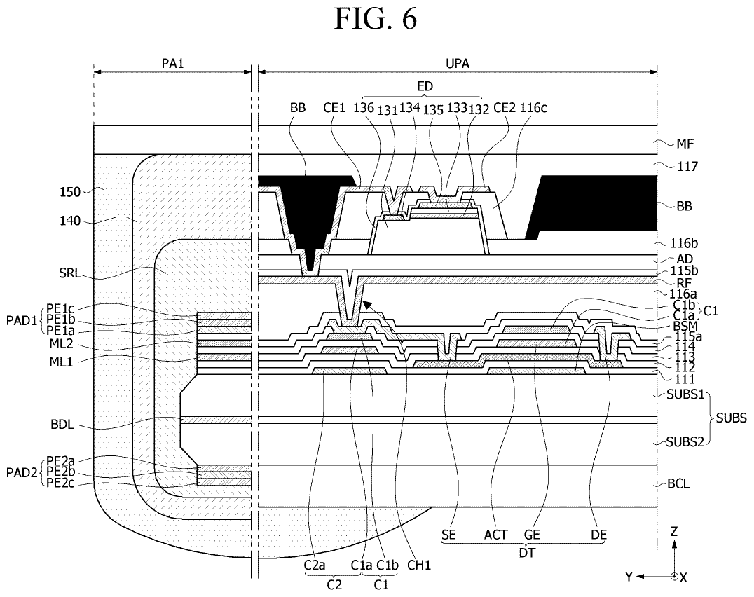

The substrate SUBS may be an insulating substrate that supports components disposed on the upper portion of a display device. The substrate SUBS may have a stacked structure of first and second substrates SUBS1, SUBS2, as shown in FIG. 6. Each of the first and second substrates SUBS1, SUBS2 may be fabricated as a glass, polymer resin, or plastic substrate. Each of the first and second substrates SUBS1, SUBS2 may be made as a flexible substrate that has flexibility, but is not limited thereto.

On one surface (or a front surface) of the substrate SUBS, a display area AA may include a plurality of pixel areas UPA, a plurality of gate driving areas GA, and a plurality of pad areas (for example, it includes a first pad area PA1 and a second pad area PA2, but not limited thereto). One or more pixels PX may be disposed in each of the pixel areas UPA. The pixel areas UPA may be arranged along a plurality of row lines and a plurality of column lines. Each of the pixels PX include a plurality of subpixels SP with different colors. Each of the subpixels SP may emit light independently, including light emitting elements and pixel circuit. The subpixels SP may include, but are not limited to, red subpixels, blue subpixels, and green subpixels.

The plurality of gate driving areas GA includes circuits for gate drivers GD. The gate driving areas GA may be formed along a row direction and/or a column direction between the plurality of pixel areas UPA. A gate driver GD formed in a gate driving area GA may provide a scan signal to a plurality of scan wrings SL.

A first pad area PA1 includes a plurality of first pad electrode PAD1 disposed on the front outermost portion of one side (or an upper side) of the display panel PN. The first pad electrodes PAD1 may transmit various signals to various wirings extending in the column direction from the display area AA. The first pad electrodes PAD1 include data pads DP connected to the data wiring DL to deliver the data voltage from the data driver DD to the data wiring DL, and gate pads GP connected to the gate driver GD to transmit clock signals, start signals, gate low voltage, gate high voltage, etc. to the gate driver GD for driving the gate driver GD. The clock signals, start signals, gate low voltages, gate high voltages, etc. for driving the gate driver GD may be generated from the timing controller TC and applied to the gate pads GP through a level shifter and a PCB. The first pad electrodes PAD1 may include a plurality of power supply wirings to which a direct current voltage (or a constant voltage) is applied.

A second pad area PA2 includes a plurality of second pad electrode PAD2 disposed on the front outermost portion of the other side (or a lower side) of the display panel PN. The second pad area PA2 may include a plurality of low-potential power supply pads VP2.

A DC voltage to be applied to the power supply wirings may be output from a power supply circuit omitted in the drawings, and may be applied to power supply pads connected to the power supply wirings through the PCB. The power supply circuit may be a DC-DC converter disposed on PCBs or control boards (for example, the first and second control boards CTB1, CTB2, but not limited thereto) arranged on the rear surface of the display panel PN to convert a DC input voltage from a main power source to a DC voltage suitable for driving the display panel PN.

The power supply pads connected to the power supply wirings may include a plurality of high-potential power supply pads VP1 disposed on the first pad area PA1 to deliver high-potential power supply voltages to high-potential power supply wirings VL1, and a plurality of low-potential power supply pads VP2 disposed on the second pad area PA2 to deliver low-potential power supply voltages to low-potential power supply wirings VL2.

The data pads DP, which are connected one-to-one to the data wirings DL, may have a relatively narrow width, while the high-potential and low-potential power supply pads VP1, VP2 and the gate pads GP may have a relatively wide width. The low-potential power supply pads VP2 may have a wider width compared to the high-potential power supply pads VP1. The widths of the pads (for example, the data pad DP, the gate pad GP, the high-potential power supply VP1, and the low-potential power supply VP2) are not limited to those shown in FIG. 5.

In order to minimize the outermost non-display area NA of the display panel PN, the pixel array, the wirings, and the pads are formed on the front surface of a substrate OSUBS of the display panel PN, and then the outermost portion of the substrate OSUBS may be cut and removed along a scribing lines indicated by a dotted line, thereby providing the substrate SUBS. After the scribing process, the rough edge of the outermost portion of the substrate OSUBS may be ground or laser trimmed. This will leave the short pad electrodes (for example, the first and second pad electrodes PAD1, PAD2, but not limited thereto) on the front outermost portion of the substrate SUBS which has been reduced in size.

The data wirings DL may extend in the column direction Y on the substrate SUBS and overlap the pixel areas UPA. The data wirings DL supply the data voltages to the respective pixel circuits of the subpixels SP. The scan wirings SL may extend in the row direction X on the substrate SUBS of the display panel PN and overlap the pixel areas UPA and the gate driving areas GA. The scan wirings SL may supply the scan signals from the gate driver GD across the pixel areas UPA and the gate driving areas GA to the respective pixel circuits of the subpixels SP.

The high-potential power supply wirings VL1 extend in the column direction Y, and at least one of them is connected in a mesh structure to auxiliary high-potential power supply wirings AVL1 extending in the row direction X. The auxiliary high-potential power supply wirings AVL1 are connected to the subpixels SP arranged in the row direction X. Therefore, the high-potential power supply voltages applied to the high-potential power supply wirings VL1 may be delivered to the subpixels SP via the auxiliary high-potential power supply wirings AVL1.

The low-potential power supply wirings VL2 extend in the column direction Y, and at least one of them is connected in a mesh structure to auxiliary low-potential power supply wirings AVL2 extending in the row direction X. The auxiliary low-potential power supply wirings AVL2 are connected to the subpixels SP arranged in the row direction X. Therefore, the subpixels SP are connected to the auxiliary low-potential power supply wirings AVL2 to which the low-potential power supply voltage is applied.

The mesh structure of the power supply wirings may allow the resistance of the power supply wirings to be reduced, which may improve the voltage drop of the high-potential power supply voltage and the deviation of the power supply voltage within the display area AA.

The substrate SUBS of the display panel PN may have one or more alignment keys (for example, a first alignment key AK1 and a second alignment key AK2, but not limited thereto) arranged between the pixel areas UPA. The alignment keys may be used for alignment in the manufacturing process of the display panel PN. A first alignment key AK1 may be disposed in the gate driving area GA. The first alignment key AK1 may be used to check the aligned position of each of the light emitting elements. The first alignment key AK1 may be formed in a cross pattern, but is not limited thereto. A second alignment key AK2 may overlap the high-potential power supply wiring VL1. The high-potential power supply wiring VL1 may include a hole formed in a position overlapping the second alignment key AK2, so that the second alignment key AK2 and the high-potential power supply wiring VL1 may be distinguished. The second alignment key AK2 may be used to align the display panel PN with a donor substrate. The donor substrate is an intermediate medium for mounting light emitting elements on the substrate SUBS of the display panel PN. A plurality of light emitting elements fabricated on a semiconductor wafer may be attached to and transferred to the donor substrate, and the light emitting elements attached to the donor substrate may be transferred onto the substrate SUBS. The second alignment key AK2 may be formed in a circular or ring pattern, but is not limited thereto.

FIG. 6 is a cross-sectional view illustrating a cross-sectional structure of the display panel according to one embodiment of the present disclosure.

Referring to FIG. 6, a pixel circuit for driving a light emitting element ED is disposed in each of a plurality of subpixels SP on a first substrate SUBS1. The pixel circuit may include a plurality of thin film transistors and one or more capacitors. In FIG. 6, a driving transistor DT, a first capacitor C1, and a second capacitor C2 are illustrated in the pixel circuit for ease of description, but other circuit elements may also be included.

A pattern of a first metal layer may be disposed on a first substrate SUBS1. The pattern of the first metal layer may include a light shielding layer BSM. The light shielding layer BSM may block light from entering an active layer ACT of the driving transistor DT to minimize leakage current. The light shielding layer BSM may be formed of an opaque conductive material, e.g., a metal such as copper (Cu), aluminum (Al), molybdenum (Mo), nickel (Ni), titanium (Ti), chromium (Cr), an alloy of these metals, or a multilayer of metal layers.

A buffer layer 111 may be disposed on the light shielding layer BSM. The buffer layer 111 may block the penetration of moisture or impurities through the first substrate SUBS1. The first metal layer may be formed of silicon oxide (SiOx), silicon nitride (SiNx), or a multilayer of insulating layers.

The driving transistor DT including the active layer ACT, a gate electrode GE, a source electrode SE, and a drain electrode DE may be disposed on the buffer layer 111.

The active layer ACT may be made of a semiconductor material such as, but not limited to, an oxide semiconductor, amorphous silicon, or polysilicon. A gate insulating layer 112 electrically isolates the active layer ACT and the gate electrode GE of the driving transistor DT. The gate insulating layer 112 may be formed of silicon oxide (SiOx), silicon nitride (SiNx), or a multilayer of insulating layers.

A pattern of a second metal layer may be disposed on the gate insulating layer 112. The pattern of the second metal layer may include the gate electrode GE of the driving transistor DT. The second metal layer may be formed of copper (Cu), aluminum (Al), molybdenum (Mo), nickel (Ni), titanium (Ti), chromium (Cr), or a multilayer of metal layers.

A first interlayer insulating layer 113 and a second interlayer insulating layer 114 are disposed on the gate electrode GE. The first interlayer insulating layer 113 and the second interlayer insulating layer 114 have contact holes formed therein for connecting the source electrode SE and the drain electrode DE of the driving transistor DD to the active layer ACT, respectively. Each of the first interlayer insulating layer 113 and the second interlayer insulating layer 114 may be formed of silicon oxide (SiOx), silicon nitride (SiNx), or a multilayer of insulation layers.

A pattern of a third metal layer may be disposed on the second interlayer insulating layer 114. The pattern of the third metal layer may include the source electrode SE and the drain electrode DE overlapping the active layer ACT and connected to the active layer ACT through the contact holes that penetrate the first and second interlayer insulating layers 113, 114. The source electrode SE may be connected to the capacitors C1, C2 and the first electrode 134 of the light emitting element ED. The third metal layer may be formed of copper (Cu), aluminum (Al), molybdenum (Mo), nickel (Ni), titanium (Ti), chromium (Cr), or a multilayer of metal layers.

The first capacitor C1 includes a first capacitor electrode C1a and a second capacitor electrode C1b. The first capacitor electrode C1a may be formed as the pattern of the second metal layer disposed on the gate insulating layer 112. The second capacitor electrode C1b is formed as the pattern of a fourth metal layer disposed on the first interlayer insulating layer 113 and overlaps the first capacitor electrode C1a with the first interlayer insulating layer 113 interposed therebetween. The second capacitor electrode C1b may be connected to the source electrode SE of the driving transistor DT. The fourth metal layer may be formed of copper (Cu), aluminum (Al), molybdenum (Mo), nickel (Ni), titanium (Ti), chromium (Cr), or a multilayer of metal layers.

The second capacitor C2 includes a third capacitor electrode C2a overlapping the first capacitor electrode C1a with the buffer layer 111 and the gate insulating layer 112 interposed therebetween. The third capacitor electrode C2a may be formed as the pattern of the first metal layer disposed on the first substrate SUBS1.

The second capacitor C2 is electrically connected between the source electrode SE of the driving transistor DT and the light emitting element ED to increase the capacitance of the light emitting element ED, which may increase the brightness when the light emitting element ED emits light.

A first passivation layer 115a covers the pattern of the third metal layer and the second interlayer insulating layer 114 so as to cover the pattern of the third metal layer. The first passivation layer 115a may be formed of silicon oxide (SiOx), silicon nitride (SiNx), or a multilayer of insulating layers.

A first planarization layer 116a is disposed on the first passivation layer 115a. The first planarization layer 116a may be formed of silicon oxide (SiOx), silicon nitride (SiNx), or a multilayer of insulating layers. The first planarization layer 116a covers the first passivation layer 115a to planarize the surface on which the light emitting element is disposed. The first leveling layer 116a may be a thick single layer or a multilayer of organic insulating layers made of benzocyclobutene or acryl-based organic material.

A pattern of a fifth metal layer may be disposed on the first planarization layer 116a. The pattern of the fifth metal layer may include a reflective layer (or light reflective layer) RF. The reflective layer RF may reflect light from the light emitting element ED toward the front surface of the display panel PN to increase light efficiency, and may be used as an electrode to connect the light emitting element ED to the pixel circuit or the power supply wirings. The reflective layer RF may be electrically connected to the source electrode SE of the driving transistor DT and the first capacitor C1 via a contact hole CHI penetrating the first planarization layer 116a and the first passivation layer 115a. Further, the reflective layer RF may be electrically connected to a first electrode 134 of the light emitting element ED via a first connection electrode CE1, or may be electrically connected to a second electrode 135 of the light emitting element ED via the high-potential power supply wiring VL1. The fifth metal layer may be formed of a transparent electrode material such as silver (Ag), aluminum (Al), molybdenum (Mo), titanium (Ti), indium tin oxide (ITO), or a multilayer of metal layers.

A second passivation layer 115b covers the pattern of the fifth metal layer and the first planarization layer 116a. The second passivation layer 115b may be formed of silicon oxide (SiOx), silicon nitride (SiNx), or a multilayer of insulating layers.

An adhesive layer AD may be disposed on the second passivation layer 115b to secure the light emitting element ED. The adhesive layer AD may be formed of a photocurable resin that can be cured by light. The adhesive layer AD may be formed of, but is not limited to, an acrylic-based material containing a photosensitive agent. The adhesive layer AD may be formed on the front surface of the first substrate SUBS1 except for the first and second pad areas PA1, PA2 in which the first pad electrode PAD1 is to be disposed.

A light emitting element ED of each of the subpixels SP may be disposed on the adhesive layer AD. Light emitting elements ED may emit light by a current from the driving transistor DT. The light emitting elements ED may include red light emitting elements, green light emitting elements, and blue light emitting elements. The light emitting elements ED may be a light emitting diode (LED) or a micro LED.

Each of the light emitting elements ED includes a first semiconductor pattern 131, a light emitting layer 132, a second semiconductor pattern 133, the first electrode 134, and the second electrode 135.

The first semiconductor pattern 131 is disposed on the adhesive layer AD, and the second semiconductor pattern 133 is disposed on the first semiconductor pattern 131. The first semiconductor pattern 131 and the second semiconductor pattern 133 may be formed as semiconductor patterns obtained by doping the conductor material with n-type and p-type impurities. For example, each of the first semiconductor pattern 131 and the second semiconductor pattern 133 may be a layer in which an n-type or p-type impurities are doped into a material such as gallium nitride (GaN), indium aluminum phosphide (InAIP), gallium arsenide (GaAs), and the like. And, the p-type impurities may be magnesium, zinc (Zn), beryllium (Be), etc., and the n-type impurities may be silicon (Si), germanium, tin (Sn), etc., but are not limited thereto.

A light emitting layer 132 is disposed between the first semiconductor pattern 131 and the second semiconductor pattern 133. The light emitting layer 132 may emit light by receiving holes and electrons from the first semiconductor pattern 131 and the second semiconductor pattern 133. The light emitting layer 132 may be formed of a single layer or multi-quantum Well (MQW) structure, and may be made, for example, of indium gallium nitride (InGaN) or gallium nitride (GaN).

The first planarization layer 134 is disposed on the first passivation layer 131. The first electrode 134 electrically connects the driving transistor DT and the first semiconductor pattern 131. The first semiconductor pattern 131 may be formed as a semiconductor layer doped with n-type impurities. The first electrode 134 may be an anode electrode of the light emitting element ED disposed on the first semiconductor pattern 131 and electrically connected to the driving transistor DT and the first and second capacitors C1, C2 via the reflective layer RF. The first electrode 134 may be disposed on an upper surface of the first semiconductor pattern 131. The first electrode 134 may be made of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The second electrode 135 is disposed on the second semiconductor pattern 133. The second electrode 135 electrically connects the high-potential power supply wiring VL1 and the second semiconductor pattern 133. The second semiconductor pattern 133 may be formed as a semiconductor layer doped with n-type impurities. The second electrode 135 may be a cathode electrode of the light emitting element ED. The second electrode 135 may be made of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The light emitting element ED may include a sealing layer 136. The sealing layer 136 covers the first and second semiconductor patterns 131, 133 and the first and second electrodes 134, 135 to protect the light emitting element ED. The sealing layer 136 and a third planarization layer 116c include contact holes exposing the first electrode 134 and the second electrode 135. The first connection electrode CE1 is connected to the reflective layer RF via a first contact hole penetrating the sealing layer 136 and the third planarization layer 116c. A second connection electrode CE2 is connected to the second electrode 135 via a second contact hole penetrating the sealing layer 136 and the third planarization layer 116c. Meanwhile, a portion of a lateral surface of the first semiconductor pattern 131 may be exposed without the sealing layer 136.

The second planarization layer 116b and the third planarization layer 116c may cover the adhesive layer AD and the light emitting element ED. The second planarization layer 116b is in contact with the lateral lower end of the light emitting element ED to secure the light emitting element ED. The third planarization layer 116c covers the light emitting element ED over the second planarization layer 116b. The third planarization layer 116c includes contact holes exposing the first electrode 134 and second electrode 135 of the light emitting element ED. The second planarization layer 116b and the third planarization layer 116c may be formed of a single layer or a multilayer of organic insulating materials, for example, photoresists or acryl-based organic materials.

A pattern of a sixth metal layer may be disposed on the third planarization layer 116c. The sixth metal layer includes the first connection electrode CE1 and the second connection electrode CE2. The first connection electrode CE1 electrically connects the first electrode 134 of the light emitting element ED and the reflective layer RF. The first connection electrode CE1 may be connected to the first electrode 134 of the light emitting element ED via a contact hole penetrating the insulating layers including the third planarization layer 116c and the sealing layer 136, and may be connected to the reflective layer RF via a contact hole penetrating the insulating layers including the second passivation layer 115b, the adhesive layer AD, the second planarization layer 116b, and the third planarization layer 116c.

The second connection electrode CE2 is connected to the second electrode 135 of the light emitting element ED via a contact hole penetrating the insulating layers including the third planarization layer 116c and the sealing layer 136. The second connection electrode CE2 may be connected to the low-potential power supply wiring VL2.

A bank pattern BB may be disposed on the second planarization layer 116b. The bank pattern BB may be spaced apart from the light emitting element ED at regular intervals. The bank pattern BB may cover a portion of the first connection electrode CE1 present in a contact hole penetrating the insulating layers including the second and third planarization layer 116b, 116c. The bank pattern BB may reduce color mixing between subpixels SP by preventing optical crosstalk between subpixels SP. To this end, the bank pattern BB may be formed of black resin, but is not limited thereto.

A first protective layer 117 may cover the patterns including the first and second connection electrodes CE1, CE2 of the sixth metal layer, the bank pattern BB, and the second planarization layer 116b, and the third planarization layer 116c. The first protective layer 117 may be formed of a light-transmitting epoxy, a single layer of silicon oxide (SiOx), silicon nitride (SiNx), a multilayer of insulating layers, or the like.

Each of the first pad electrodes PAD1 disposed in the first and second pad areas PA1, PA2 of the first substrate SUBS1 may have a multilayer structure of metal layers. For example, each of the first pad electrodes PAD1 may include a first pad metal layer PE1a, a second pad metal layer PE1b, and a third pad metal layer PE1c stacked on the front outermost portion of the first substrate SUBS1.

The pattern of the third metal layer disposed on the second interlayer insulating layer 114 may further include the first pad metal layer PE1a. The first pad metal layer PE1a may be formed of the same metal as the source electrode SE and drain electrode (DE) of the driving transistor (DT), such as copper (Cu), aluminum (Al), molybdenum (Mo), nickel (Ni), titanium (Ti), chromium (Cr), or a multilayer of metal layers.

The pattern of the fifth metal layer disposed on the first planarization layer 116a may further include the second pad metal layer PE1b. The second pad metal layer PE1b may be formed of the same metal as the reflective layer RF, for example, silver (Ag), aluminum (Al), molybdenum (Mo), or a multilayer of metal layers.

The pattern of the sixth metal layer disposed on the third planarization layer 116c may further include the third pad metal layer PE1c. The third pad metal layer PE1c may be formed of the same conductive material as the first connection electrode CE1 and the second connection electrode CE2, for example, a transparent conductive material such as indium tin oxide (ITO) or indium zinc oxide (IZO), or a multilayer metal layer, etc.

A first metal layer ML1 and a second metal layer ML2 and a plurality of insulating layers may be disposed under the first pad electrodes PAD1. By disposing the first metal layer ML1, the second metal layer ML2, and the plurality of insulating layers under the first pad electrode PAD1, the step difference of the first pad electrodes PAD1 may be adjusted. For example, the buffer layer 111, the gate insulating layer 112, the first metal layer ML1, the first interlayer insulating layer 113, and the second metal layer ML2 may be sequentially disposed between the first pad electrode PAD1 and the first substrate SUBS1. The pattern of the second metal layer disposed on the gate insulating layer 112 may include the first metal layer ML1. The pattern of the fourth metal layer disposed on the first interlayer insulating layer 113 may include the second metal layer ML2. The plurality of the insulating layers and the second and third metal layers ML2, ML3 under the first pad electrodes PAD1 are not limited to those layers as shown in FIG. 6.

A second substrate SUBS2 may be disposed on the rear surface of the first substrate SUBS1. A bonding layer BDL is disposed between the first substrate SUBS1 and the second substrate SUBS2. The bonding layer BDL may be cured by different curing methods to bond the first substrate SUBS1 and the second substrate SUBS2. The bonding layer BDL may be disposed in only a portion of the area between the first substrate SUBS1 and the second substrate SUBS2, or it may be disposed in the entire area between the first substrate SUBS1 and the second substrate SUBS2. The first substrate SUBS1 and the second substrate SUBS may be scribed and ground simultaneously so that the lateral surfaces of the first substrate SUBS1 and the second substrate SUBS do not have a step difference.

A plurality of second pad electrodes PAD2 may be disposed on the rear outermost portion of the second substrate SUBS2. The second pad electrodes PAD2 are electrically connected to the side wirings SRL and the first pad electrode PAD1 to transmit signals from circuit components disposed on the rear surface of the second substrate SUBS2 to the subpixels SP disposed on the front surface (or upper surface) of the first substrate SUBS1.

Each of the second pad electrodes PAD2 may have a multilayer structure of metal layers. For example, each of the second pad electrodes PAD2 may include a first pad metal layer PE2a, a second pad metal layer PE2b, and a third pad metal layer PE2c stacked on the rear outermost portion of the second substrate SUBS2. Each of the first and second pad metal layers PE2a, PE2b may be formed of copper (Cu), aluminum (Al), molybdenum (Mo), nickel (Ni), titanium (Ti), chromium (Cr), or a multilayer of metal layers. The third pad metal layer PE2c may be formed of a transparent conductive material such as indium tin oxide (ITO) or indium zinc oxide (IZO).

A second protective layer BCL may be disposed on the rear surface of the second substrate SUBS2. The second protective layer BCL may cover various wirings except for the second pad electrodes PAD2 on the rear surface of the second substrate SUBS2. The second protective layer BCL may be made of an organic insulating material, for example, a benzocyclobutene or acryl-based organic insulating material.

Circuit components such as a plurality of flexible films and PCBs may be disposed on the rear surface of the second substrate SUBS2. The output terminals of the flexible film are electrically connected to the second pad electrode PAD2, and the input terminals of the flexible film are electrically connected to the output terminals of the PCB. Accordingly, a signal or voltage output from a PCB may be transmitted to the subpixels SP disposed on the front surface of the first substrate SUBS1 via the flexible film, the second pad electrode PAD2, the side wiring SRL, the plurality of first pad electrodes PAD1, and the wiring connected to the first pad electrode PAD1.

The side wirings SRL electrically connect the first pad electrodes PAD1 and the second pad electrodes PAD2 across the side surfaces of the first substrate SUBS1 and the second substrate SUBS2. The side wirings SRL may be formed on the side surfaces of the first and second substrates SUBS1, SUBS2 by a pad printing method using conductive inks, for example, the conductive inks including silver (Ag), copper (Cu), molybdenum (Mo), and chromium (Cr).

A side insulating layer 140 may cover the side wirings SRL formed on the outermost front, side, and rear surfaces of the first and second substrates SUBS1 and SUBS2 bonded together. If the side wirings are metal, external light may be reflected from the side wirings or light emitted by the emitting device ED may be reflected from the side wirings and be visible to the user. In order to improve image deterioration due to such reflected light, the side insulating layer 140 may include a black material that absorbs external light. For example, the side insulating layer 140 may be formed on the outermost portion of the first and second substrates SUBS1, SUBS2 with black ink that can be applied by a printing method.

A seal 150 may cover the side insulating layer 140 to protect the display panel PN from external shock, moisture, oxygen, etc. For example, the seal 150 may be made of an insulating material such as polyimide (PI), poly urethane, epoxy, acryl-based insulating material, or the like.

A functional film MF may cover the front surface of the display panel PN. The functional film MF may be one or more of a variety of functional films, such as an anti-scattering film, an anti-glare film, an anti-reflective film, a low-reflective film, an Oled transmittance controllable film for a luminance enhancement, a color difference compensation film, a polarizing plate, and the like. The anti-scattering film prevents substrate fragments or particles from scattering when the display panel PN is damaged. The functional film MF may be cut and removed together with the outer portion of the seal 150 along a cut line that overlaps with the seal 150 after the seal 150 has been broadly bonded to the front surface of the first substrate SUBS1. As a result, the outermost exposed side surface of the functional film MF and the seal 150 may form a coplanar side surface without a step difference.

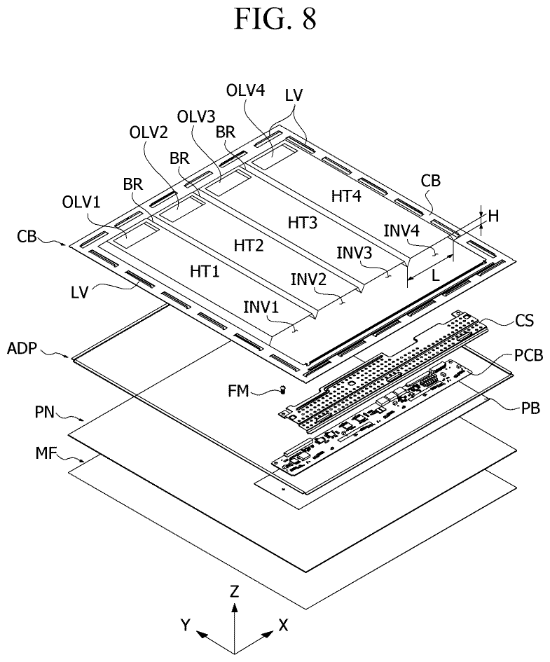

FIG. 7 is a plan view illustrating a rear surface of the display module according to one embodiment of the present disclosure. FIG. 8 is an exploded perspective view illustrating the display module according to one embodiment of the present disclosure.

Referring to FIGS. 7 and 8, each of the display modules includes a display panel PN, a PCB disposed on a rear surface of the display panel PN, and a cover bottom CB.

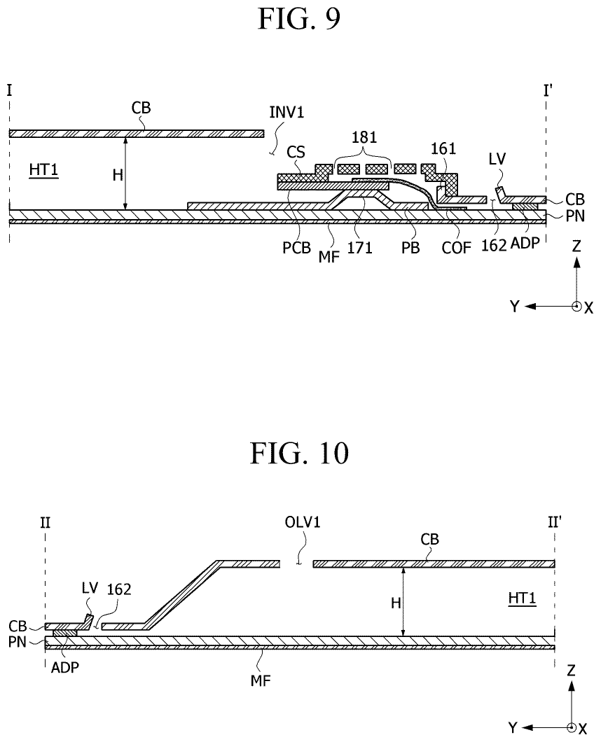

The display module further includes a plurality of flexible films COF (as shown in FIG. 9) that connect second pad electrodes PAD2 disposed on the outermost portion of the rear surface of the display panel PN to output terminals on the PCB. An IC having integrated circuits of the data driver DD and/or the gate driver GD may be mounted on at least one of the flexible films COF. The flexible films COF may be bonded to the rear surface of the display panel PN via an anisotropic conductive film (ACF).

The PCB located on one side of the display module, e.g. at the lower end, has various circuit elements for driving the display panel PN. For example, a PCB may have a power supply IC chip (or PMIC), which is a device used to generate various voltages, such as high-potential power supply, low-potential power supply, and reference power supply. The circuit elements disposed on the PCB may generate heat during operation. In particular, because the heating temperature of a power IC chip and an inductor is high, it may cause a temperature difference in the display panel PN by increasing the temperature in the area where the PCB is placed in the display module, such as a lower part of the display module. This temperature difference may be a major factor that causes spots or color differences to be visible when images are displayed on the pixels of the display panel PN.

The PCB is electrically connected to a plurality of flexible films COF. The input terminals of the PCB may be electrically connected to the output terminals of the first and second control boards CTB1, CTB2 as shown in FIG. 4. A plurality of wirings and a plurality of circuit elements may be mounted on the PCB.

The display module may further include a plate bottom (in other words, bottom plate) PB disposed below the PCB, and a cover shield (in other words, shield cover) CS disposed above the PCB. The plate bottom PB and the cover shield CS may be made of materials with high thermal conductivity and rigidity.

The plate bottom PB, the PCB, and the cover shield CS include one or more fastening holes, such as pem-nuts, that overlap each other. Fastening members FM, for example, pem bolts may be engaged in the fastening holes in the plate bottom PB, the PCB, and the cover shield CS to join the plate bottom PB, the PCB, and the cover shield CS into a stacked structure.

The display module may further include a cover bottom CB covering at least a portion of a rear surface of the display panel PN. The cover bottom CB may be made of a material that is rigid and has high thermal conductivity, for example, a metal such as aluminum (Al), copper (Cu), zinc (Zn), silver (Ag), gold (Au), iron (Fe), steel (SUS) or Invar, or plastic.

The plate bottom PB may dissipate heat generated from the PCB for heat radiation. The plate bottom PB is placed between the PCB and the display panel PN to mitigate the concentration of heat from the PCB in certain areas of the display panel PN.

The plate bottom PB includes a protrusion 171 that projects toward the PCB at a portion where it overlaps the PCB, as shown in FIG. 9. The protrusion 171 may support the PCB from below and may improve the rigidity of the plate bottom PB. The top surface of the protrusion 171 may be in direct contact with the PCB. Heat generated from the PCB may be distributed throughout the plate bottom PB via the protrusions 171.

The cover shield CS may cover the PCB to protect the PCB from external impact. As shown in FIG. 9, one end of the cover shield CS may include a protrusion that is bent in an “L” shape to engage the protrusion 161 of the cover bottom CB. The engagement structure of the cover shield CS and the cover bottom CB thus limits the movement of the cover shield CS and guides the position of the cover shield CS to be assembled.

The cover shield CS includes a plurality of heat dissipation holes 181, as shown in FIG. 9. The heat dissipation holes 181 may be evenly distributed and arranged on the cover shield CS. The heat dissipation holes 181 allow heat generated from the PCB to escape to the outside through the cover shield CS. The cover shield CS may be opened at high-temperature hot spots in the heat distribution of the PCB, for example, at the IC or the inductor. In this case, the high-temperature hot spots of the PCB may be exposed without being covered by the cover shield CS, allowing the heat to radiate directly to the outside. In other embodiments, the heat dissipation holes 181 may be arranged such that the diameter of the heat dissipation holes 181 formed in the cover shield CS is increased or the density of the heat dissipation holes is increased in areas that overlap with areas of high heat generation as determined from a result of measuring the heat distribution of the PCB.

Each of the display modules of the present disclosure utilizes natural convection of the updraft caused by the buoyancy generated by the heat of the PCB to reduce the temperature difference between the display panels PN, rather than utilizing forced convection requiring electric fans.

The cover bottom CB covers the rear surface of the display panel PN to protect the display panel PN, and the cover bottom CB causes the updraft to be distributed to the relatively low temperature portion in the display panel PN and released to the outside when the heat generated from the PCB moves upward due to the buoyancy, thereby reducing the temperature difference in the display panel PN. The cover bottom CB has a longitudinal framework structure, such as the planar shape of the display panel PN, and provides one or more heat dissipation tunnels in which a portion of the cover bottom CB through which the plate bottom PB, the PCB, and the cover shield CS are stacked, is opened so that the heat from the PCB moves upward by buoyancy.

The display module may further include an adhesive member ADP for joining the display panel PN and the cover bottom CB. The adhesive member ADP may be disposed between the cover bottom CB and the display panel PN along the edge of the display module. The adhesive member ADP may be, but is not limited to, foam tape with double-sided adhesion.

The display module may further include a heat dissipation sheet disposed between the PCB and the display panel PN. The heat dissipation sheet is omitted from the drawing. The heat dissipation sheet may be made of any material with high thermal conductivity, such as, but not limited to, graphite, aluminum (Al), and copper (Cu). The heat dissipation sheet may be bonded to the PCB and the display panels PN with adhesive materials such as double-sided adhesive tapes, but are not limited thereto.

FIG. 9 is a cross-sectional view illustrating an inlet of a cover bottom, cut along line “I-I′” in FIG. 7; and FIG. 10 is a cross-sectional view illustrating an outlet of the cover bottom, cut along line “II-II” in FIG. 7.

Referring to FIGS. 7 to 10, the cover bottom CB includes a plurality of openings 162 disposed along the periphery of the display panel PN, and protrusions LV formed on one side of the respective openings 162. The protrusions LV are parts of the cover bottom CB which are bent out of the rear surface of the display module. Each of the openings 162 may be formed by a portion of the cover bottom CB removed or displaced by projecting the protrusions LV upward.

The protrusions LV may be used to join neighboring display modules on the same plane in a tiled display such as the one shown in FIG. 3. The protrusions LV may project at an angle of 45 degrees or more or an angle of 90 degrees or less (in other words, at an angle of not less than 45 degrees and not more than 90 degrees) from the plane of the cover bottom CB parallel to the back plane (or rear surface) of the display module.

The cover bottom CB may include one or more heat dissipation tunnels, for example, heat dissipation tunnels HT1 to HT4. The cover bottom CB forms the top and side surfaces of the heat dissipation tunnels HT1 to HT4. When the heat from the PCB moves upward due to the buoyancy, it moves upward across the relatively low temperature portion of the display panel PN through the inside of each of the heat dissipation tunnels HT1 to HT4 and is discharged to the outside. As the hot updraft within the heat dissipation tunnels HT1 to HT4 passes over the display panel PN, the temperature of the PCB decreases, and the temperature of the relatively low temperature portion of the display panel PN increases, thus reducing the temperature difference across the entire display panel screen.

The cover bottom CB is opened at inlets INV1 to INV4 and outlets OLV1 to OLV4 of the heat dissipation tunnels HT1 to HT4. The inlets INV1 to INV4 are spaced apart from the PCB at a distance on one side (or one end) of the rear surface of the display panel PN. The outlets OLV1 to OLV4 are located on the other side (or the other end) of the rear surface of the display panel PN to discharge the updraft rising across the rear surface of the display panel PN.

One or more inlets (for example, inlets INV1 to INV4) through which the cover bottom CB is opened are formed on one side of the heat dissipation tunnels HT1 to HT4 close to the PCB, and one or more outlets (for example, outlets OLV1 to OLV4) are arranged on the top side (or upper surface) of the heat dissipation tunnels HT1 to HT4 away from the PCB. Each of the inlets INV1 to INV4 may be larger in size than each of the outlets OLV1 to OLV4.

The updraft from the PCB enters the heat dissipation tunnels HT1 to HT4 through the inlets INV1 to INV4 of the heat dissipation tunnels HT1 to HT4 and rises by the buoyancy. The hot updraft rising within the heat dissipation tunnels HT1 to HT4 may raise the temperature of the relatively low temperature portion of the display panel PN and may then be discharged to the outside through the outlets OLV1 to OLV4.

The cover bottom CB includes one or more bulkheads BR for individual partitioning of the heat dissipation tunnels HT1 to HT4. The bulkheads BR of the cover bottom CB are the parts of the cover bottom CB that protrude from the boundary between the heat dissipation tunnels HT1 to HT4 towards the display panel PN. The bulkheads BR may be spaced apart from and not in direct contact with the rear surface of the display panel PN, and may be opposite to the rear surface of the display panel PN.

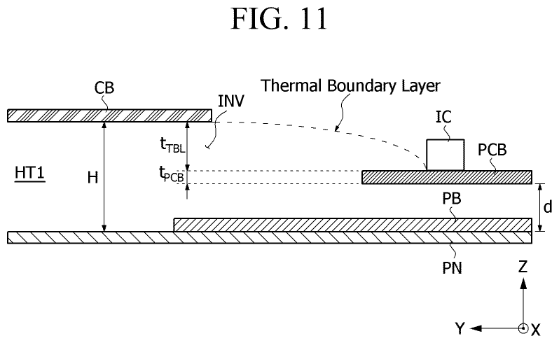

FIG. 11 is a cross-sectional view illustrating the geometric relationship between components on a rear surface of a display module.

Referring to FIGS. 9 to 11, the display panel PN has a uniform thickness and a flat rear surface. The plate bottom PB is disposed on the rear surface of the display panel PN parallel to the display panel PN and has a uniform thickness. The PCB is spaced from the plate bottom PB and is disposed parallel to the plate bottom PB, and has a uniform thickness t_{PCB}. The cover bottom CB may have a uniform thickness. Between the inlets INV1 to INV4 and the outlets OLV1 to OLV4 of the heat dissipation tunnels HT1 to HT4, a forming height H between the rear surface of the display panel PN and the cover bottom CB is greater than the height ‘d’ between the rear surface of the display panel PN and the PCB. The forming height H may be interpreted as the height of the heat dissipation tunnels HT1 to HT4.

In FIG. 11, t_{TBL} is the thickness of a thermal boundary layer (TBL). The thermal boundary layer is formed from the heat source IC on the PCB to the cover bottom CB on the inlet side of the heat dissipation tunnel HT1 to HT4 between them. The heat source IC may be an IC chip or an inductor mounted on the PCB.

As shown in FIG. 11, the components disposed on the rear surface of the display panel PN satisfy the following relationship: H>t_{TBL}>d>t_{PCB}.

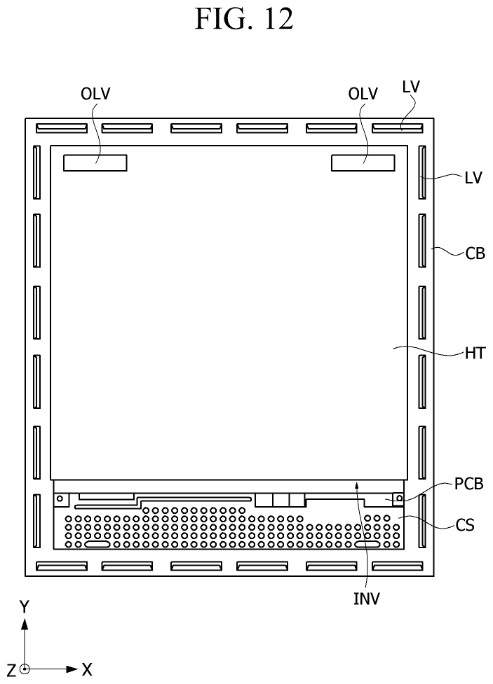

FIG. 12 is a plan view illustrating a rear surface of a display module according to another embodiment of the present disclosure.

Referring to FIG. 12, the cover bottom CB may include one heat dissipation tunnel HT. The heat dissipation tunnel HT includes one large inlet INV close to the PCB and multiple outlets OLV formed at a location far from the PCB. The top surface (or top wall) and side walls (or side surfaces) of the heat dissipation tunnel HT are formed by the cover bottom CB. In this case, the side walls of the heat tunnel HT are located on either side of the outermost portion of the display module or display panel PN.

As described above and according to one embodiment of the present disclosure, the cover bottom CB forms the top and side surfaces of the heat dissipation tunnels HT1 to HT4. When the heat from the PCB moves upward due to the buoyancy, it moves upward across the relatively low temperature portion of the display panel PN through the inside of each of the heat dissipation tunnels HT1 to HT4 and is discharged to the outside. As the hot updraft within the heat dissipation tunnels HT1 to HT4 passes over the display panel PN, the temperature of the PCB decreases, and the temperature of the relatively low temperature portion of the display panel PN increases, thus reducing the temperature difference across the entire display panel screen.

The updraft is generated by the heat from the heat sources (e.g., the ICs) mounted on the PCB. In general, the Prandtl number in air is 0.7, so t_{TBL} is calculated to be approximately 3 mm. When d=2 mm, the forming height H is t_{TBL}+t_{PCB}+d, as shown in FIG. 11. Ignoring the t_{PCB}, the forming height H is H=3 mm+2 mm=5 mm.

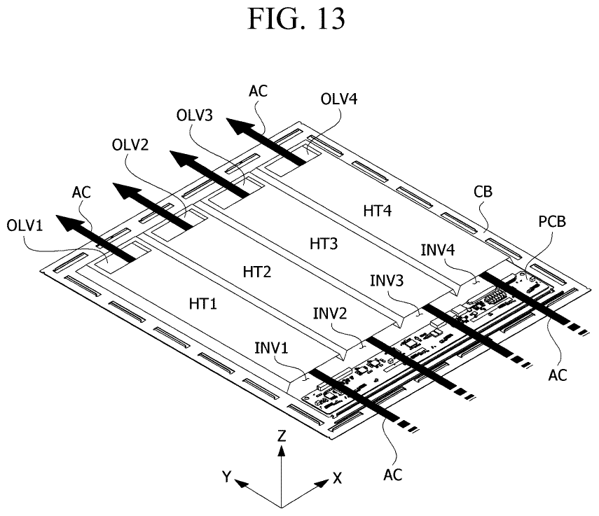

The inventors conducted a simulation to verify the effectiveness of compensating the temperature difference of the display panel PN due to the heat dissipation tunnels HT1 to HT4. FIGS. 13 to 17 are drawings illustrating the simulation. FIG. 13 shows that an updraft AC generated by the heat source on the PCB enters the four heat dissipation tunnels HT1 to HT4 and discharge across the rear surface of the display panel PN.

When the forming height H is less than or equal to the height ‘d’ between the display panel PN and the PCB, for example, 2 mm or less, there is practically no flow of the updraft from the heat source IC on the PCB into the heat dissipation tunnels HT1 to HT4. When the forming height H is more than four times the height d between the display panel PN and the PCB, e.g., 10 mm, the relatively low temperature outside air is introduced into the heat dissipation tunnels HT1 to HT4 together with the heat from the PCB. Since the effectiveness of reducing the temperature difference of the display panel PN is reduced when the low temperature outside air is introduced into the heat dissipation tunnels HT1 to HT4, the forming height H is preferably set at a height that allows the heat from the PCB to enter the heat dissipation tunnels HT1 to HT4 and allows less the outside air to enter.

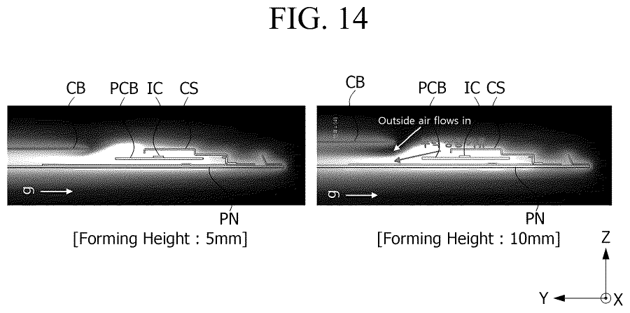

Referring to FIG. 14, the left image shows the simulation result in which the relatively low temperature outside air enters the heat dissipation tunnels HT1 to HT4 along with the updraft from the heat source IC on the PCB, when the forming height H is 5 mm. The right image shows the simulation result in which the relatively low temperature outside air enters the heat dissipation tunnels HT1 to HT4 along with the updraft from the heat source IC on the PCB when the forming height H is 10 mm. In FIG. 14, ‘g’ denotes gravity.

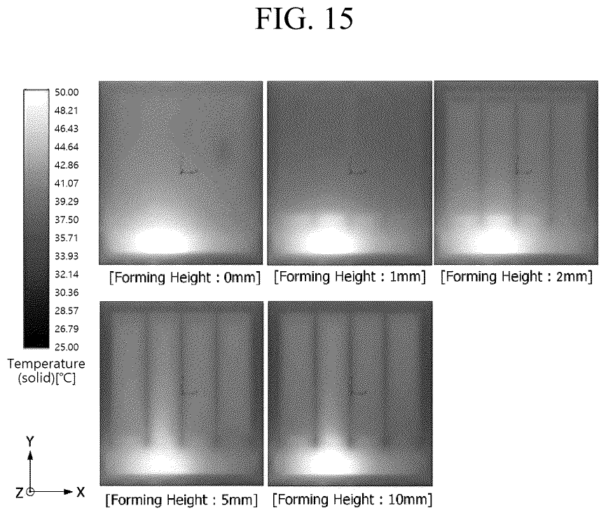

Referring to FIGS. 15 to 17, the temperature distribution of the display panel PN as determined by the simulation is shown when the forming height H is 0 mm, 1 mm, 2 mm, 5 mm, and 10 mm. As can be seen from FIG. 15, when the forming height H is 5 mm, the temperature difference with the maximum temperature of the display panel PN is the smallest.

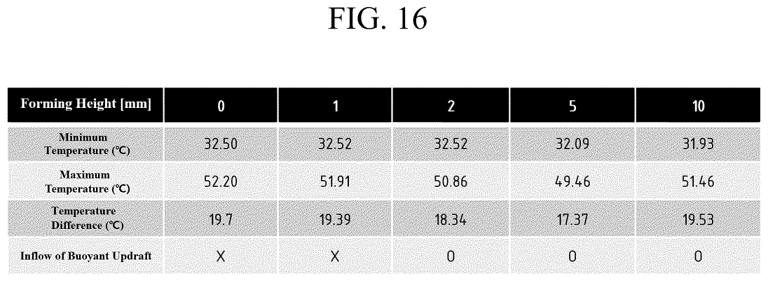

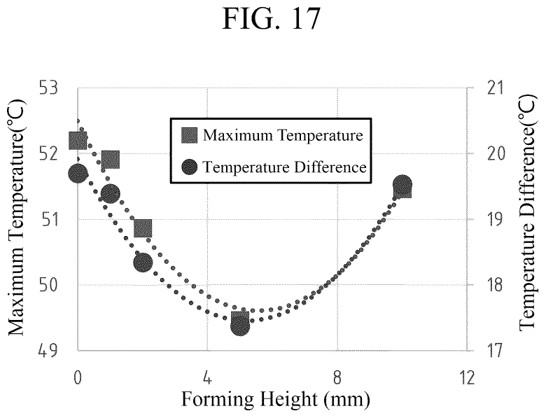

Referring to FIGS. 16 and 17, it is confirmed that when the forming height (H) is 3 mm to 7 mm, the maximum temperature [° C.] of the display panel PN and the temperature difference [° C.] of the maximum temperature minus the minimum temperature are significantly reduced. When the forming height H is 5 mm, the temperature difference [C] of the display panel PN is the smallest.

The flow pattern of the updraft may depend on the formation of the heat dissipation tunnels HT1 to HT4 at the cover bottom CB, i.e., the channels through which the updraft flows. Since the updraft is not forced convection, turbulence may actually impede the flow if it occurs. For uniform laminar flow, it is desirable to form a flow path that induces natural convection in the laminar flow region, since natural convection in the updraft due to the buoyancy rises rapidly over the shortest distance.

To evaluate the flow of the updrafts due to, the inventors calculated the dimensionless number Grashof number (Gr) as shown in Equation 1. In Equation 1, the height of the heat dissipation tunnels HT1 to HT4 is very small, so the geometric characteristic length is set to the long side L of the inlets INV1 to INV4 as shown in FIG. 8. For a four-section heat dissipation tunnel HT1 to HT4 as shown in FIG. 8, the long side L was set as L=80 [mm]. For a single heat dissipation tunnel as shown in FIG. 12, L=320 [mm] was set. As the number of flow paths, that is, the number of heat radiation tunnel divisions increases, the dimensionless number Gr decreases, and if the number becomes greater than or equal to 4, the updraft belongs to the laminar flow region (laminar flow, Gr<106). For a single heat dissipation tunnel such as in FIG. 12, the updraft falls in the transition region (transition flow, 106<Gr<108). According to the simulations and theoretical analysis, it is confirmed that the updraft due to the buoyancy generated by the heat from the PCB in the laminar flow region and the transition region can naturally convect on the rear surface of the display panel PN, which reduces the temperature deviation of the display panel PN.

In Equation 1 below, ‘g’ is the gravitational acceleration, ‘β’ is the volume expansion gradient, ‘v’ is the kinematic viscosity coefficient of a fluid, ‘Ts’ is the temperature of the heat source IC on the PCB, ‘T∞’ is the driving temperature of the display panel PN, and ‘L’ is the geometric characteristic length.

$$Gr = \frac{g β ( {T}_{s} - {T}_{∞} ) {L}^{3}}{{ν}^{2}} \qquad Equation 1$$

Where, g=9.81, β=0.002832,
   Tₛ=70, T_{∞}=45, v=2e-5

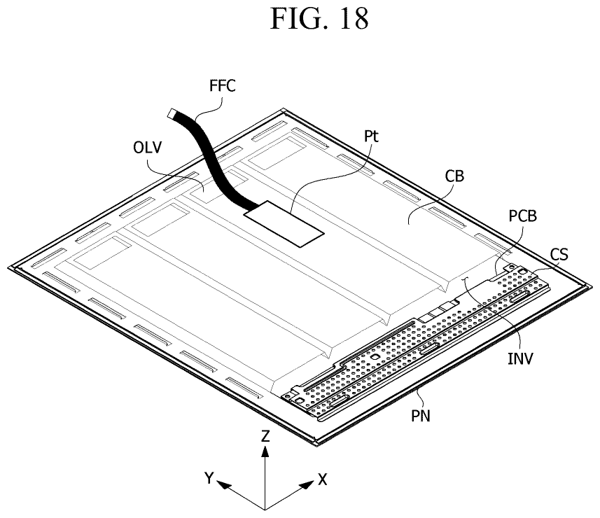

FIG. 18 is a plan view illustrating a rear surface of a display module according to further another embodiment of the present disclosure.

Referring to FIG. 18, the display module may further include a vibration generator Pt coupled to the rear surface of the display panel PN. The vibration generator Pt may include a piezoelectric device and may be disposed within the heat dissipation tunnel HT.

The vibration generator Pt is connected to the control board or the system board through a flexible film FFC to generate vibration according to the audio signal received from the timing controller TC or host system. The vibration of the vibration generator Pt is transmitted to the display panel PN, and the display panel PN acts as a diaphragm of the speaker, so that sound can be output from the display panel PN.

When the vibration generator of the speaker is placed inside an airtight cover, the diaphragm in a back speaker and a back cover may vibrate together, causing the diaphragm to vibrate abnormally and forcefully. In order to prevent this, a plurality of vent holes are formed in the cover where the speaker's vibration generator is embedded. On the contrary, in the embodiment shown in FIG. 18, the cover bottom is an open structure with the inlets (INV) and the outlets OLV, which may prevent abnormal vibration of the display panel PN.

According to one or more embodiments of the present disclosure, a display apparatus may be described as follows.

According to one or more embodiments of the present disclosure, a display device may include a display panel; a printed circuit board disposed on a rear surface of the display panel; and a cover bottom disposed on the rear surface of the display panel. The cover bottom may include at least one heat dissipation tunnel into which updraft generated by heat from the printed circuit board is introduced. The heat dissipation tunnel may include at least one inlet spaced apart from the printed circuit board on one side of the rear surface of the display panel, and at least one outlet disposed on the other side of the rear surface of the display panel, through which the updraft rising across the rear surface of the display panel is discharged.

According to one or more embodiments of the present disclosure, a plurality of light emitting elements may be disposed on a front surface of the display panel.

According to one or more embodiments of the present disclosure, the cover bottom may include a plurality of heat dissipation tunnels. Each of the plurality of heat dissipation tunnels may include the inlet and the outlet.

According to one or more embodiments of the present disclosure, the cover bottom may include a single heat dissipation tunnel. The single heat dissipation tunnel may include the inlet, and a plurality of outlets each having a size smaller than the inlet.

According to one or more embodiments of the present disclosure, a display device may further include a vibration generator disposed on the rear surface of the display panel and configured to vibrate in response to an audio signal.

According to one or more embodiments of the present disclosure, a display device may further include a flexible film configured to connect, via the outlet, an external circuit and the vibration generator in the heat dissipation tunnel.

According to one or more embodiments of the present disclosure, the heat dissipation tunnel may have a height between 3 mm and 7 mm.

According to one or more embodiments of the present disclosure, a forming height between the rear surface of the display panel and the cover bottom may be greater than the height between the rear surface of the display panel and the printed circuit board.

According to one or more embodiments of the present disclosure, a display device may satisfy the following relationship: H>t_{TBL}>d>t_{PCB}. Wherein ‘H’ denotes the forming height between the rear surface of the display panel and the cover bottom, ‘d’ denotes the height between the rear surface of the display panel and the printed circuit board, ‘t_{TBL}’ denotes the thickness of a thermal boundary layer (TBL) between a heat source of the printed circuit board and the inlet of the heat dissipation tunnel, and ‘t_{PCB}’ denotes the thickness of the printed circuit board.

According to one or more embodiments of the present disclosure, a display device may comprise a plurality of display modules arranged in a same plane. Each of the plurality of display modules may include a display panel having a front surface on which a plurality of light emitting elements are arranged, the front surface having an opposite rear surface; a printed circuit board disposed on a rear surface of the display panel; and a cover bottom disposed on the rear surface of the display panel. The cover bottom may include at least one heat dissipation tunnel into which updraft generated by heat from the printed circuit board is introduced. The heat dissipation tunnel may include at least one inlet spaced apart from the printed circuit board on one side of the rear surface of the display panel, and at least one outlet disposed on the other side of the rear surface of the display panel, through which the updraft rising across the rear surface of the display panel is discharged. The updraft from the printed circuit board may be discharged to the outside as natural convection, through the inlet of the heat dissipation tunnel, across the rear surface of the display panel, and through the outlet of the heat dissipation tunnel.

According to one or more embodiments of the present disclosure, the display device may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc.

Additionally, the display device according to one or more embodiments of the present disclosure may be applied to organic light emitting lighting devices or inorganic light emitting lighting devices.

The objects to be achieved by the present disclosure, the means for achieving the objects, and effects of the present disclosure described above do not specify essential features of the claims, and thus, the scope of the claims is not limited to the disclosure of the present disclosure.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a display panel;
a printed circuit board disposed on a rear surface of the display panel; and
a cover bottom disposed on the rear surface of the display panel,
wherein the cover bottom includes:
at least one heat dissipation tunnel into which updraft generated by heat from the printed circuit board is introduced,
the heat dissipation tunnel includes:
at least one inlet spaced apart from the printed circuit board on one side of the rear surface of the display panel; and
at least one outlet disposed on the other side of the rear surface of the display panel, through which the updraft rising across the rear surface of the display panel is discharged.

2. The display device of claim 1, wherein
a plurality of light emitting elements are disposed on a front surface of the display panel.

3. The display device of claim 1, wherein the cover bottom includes:
a plurality of heat dissipation tunnels, and
wherein each of the plurality of heat dissipation tunnels includes the inlet and the outlet.

4. The display device of claim 1, wherein the cover bottom includes:
a single heat dissipation tunnel,
the single heat dissipation tunnel includes:
the inlet; and
a plurality of outlets each having a size smaller than the inlet.

5. The display device of claim 1, further comprising:
a vibration generator disposed on the rear surface of the display panel and configured to vibrate in response to an audio signal.

6. The display device of claim 5, further comprising:
a flexible film configured to connect, via the outlet, an external circuit and the vibration generator in the heat dissipation tunnel.

7. The display device of claim 1, wherein the heat dissipation tunnel has a height between 3 mm and 7 mm.

8. The display device of claim 1, wherein a forming height between the rear surface of the display panel and the cover bottom is greater than the height between the rear surface of the display panel and the printed circuit board.

9. The display device of claim 8, wherein the display device satisfies the following relationship: H>t_{TBL}>d>t_{PCB}, and
wherein ‘H’ denotes the forming height between the rear surface of the display panel and the cover bottom, ‘d’ denotes the height between the rear surface of the display panel and the printed circuit board, ‘t_{TBL}’ denotes the thickness of a thermal boundary layer between a heat source of the printed circuit board and the inlet of the heat dissipation tunnel, and ‘t_{PCB}’ denotes the thickness of the printed circuit board.

10. A display device, comprising:
a plurality of display modules arranged in a same plane,
wherein each of the plurality of display modules includes:
a display panel having a front surface on which a plurality of light emitting elements are arranged, the front surface having an opposite rear surface;
a printed circuit board disposed on a rear surface of the display panel; and
a cover bottom disposed on the rear surface of the display panel,
the cover bottom includes:
at least one heat dissipation tunnel into which updraft generated by heat from the printed circuit board is introduced,
the heat dissipation tunnel includes:
at least one inlet spaced apart from the printed circuit board on one side of the rear surface of the display panel; and
at least one outlet disposed on the other side of the rear surface of the display panel, through which the updraft rising across the rear surface of the display panel is discharged, and
wherein the updraft from the printed circuit board is discharged to the outside as natural convection, through the inlet of the heat dissipation tunnel, across the rear surface of the display panel, and through the outlet of the heat dissipation tunnel.

11. The display device of claim 10, wherein the cover bottom includes:
a plurality of heat dissipation tunnels, and
wherein each of the plurality of heat dissipation tunnels includes the inlet and the outlet.

12. The display device of claim 10, wherein the cover bottom includes:
a single heat dissipation tunnel,
the single heat dissipation tunnel includes:
the inlet; and
a plurality of outlets each having a size smaller than the inlet.

13. The display device of claim 10, further comprising:
a vibration generator disposed on the rear surface of the display panel and configured to vibrate in response to an audio signal; and
a flexible film configured to connect, via the outlet, an external circuit and the vibration generator in the heat dissipation tunnel.

14. The display device of claim 10, wherein the heat dissipation tunnel has a height of between 3 mm and 7 mm when the printed circuit board has a thickness of 2 mm.

15. The display device of claim 10, wherein a forming height between the rear surface of the display panel and the cover bottom is greater than the height between the rear surface of the display panel and the printed circuit board.

16. The display device of claim 15, wherein the display device satisfies the following relationship: H>t_{TBL}>d>t_{PCB}, and
wherein ‘H’ denotes the forming height between the rear surface of the display panel and the cover bottom, ‘d’ denotes the height between the rear surface of the display panel and the printed circuit board, ‘t_{TBL}’ denotes the thickness of a thermal boundary layer between a heat source of the printed circuit board and the inlet of the heat dissipation tunnel, and ‘t_{PCB}’ denotes the thickness of the printed circuit board.
